(19) United States
(12) Patent Application Publication
(10) Pub. No.: US 2014/0251803 A1
(43) Pub. Date: Sep. 11, 2014

(54) CATHODIC ARC MASK ASSEMBLY LOCK SYSTEM

(71) Applicant: United Technologies Corporation, Hartford, CT (US)

(72) Inventor: Ronald R. Soucy, Tolland, CT (US)

(73) Assignee: United Technologies Corporation, Hartford, CT (US)

(21) Appl. No.: 14/199,557

(22) Filed: Mar. 6, 2014

Related U.S. Application Data
(60) Provisional application No. 61/773,608, filed on Mar. 6, 2013.

(51) Int. Cl. C23C 14/04

(52) U.S. Cl. CPC C23C 14/042
USPC 204/298.41; 29/428

(57) ABSTRACT

A mask assembly for a coating system includes a second mask that mounts to a first mask and is retained thereto by a pin. A method of masking a component for a cathodic arc vapor deposition system includes retaining a first mask to a second mask with a platter mount pin.

This application claims priority to U.S. Patent Appin. No. 61/773,608 filed Mar. 6, 2013.

### BACKGROUND

The present disclosure relates to cathodic arc deposition and, more particularly, to a mask assembly therefor.

Cathodic arc deposition is a vapor deposition technique in which an electric arc is used to vaporize material from a cathode ingot target. The vaporized material then condenses on a workpiece to form a thin film. The technique can be used to deposit metallic, ceramic, and composite films. Cathodic arc deposition is an effective production process for aerospace components such as, for example, airfoils and other components that operate in high temperature environments.

Masks utilized with cathodic arc deposition utilize mechanical fasteners to assemble the mask. The fastener can be a bolt and nut configuration or some type of lock wedge. Although effective, the fasteners become coated with the vaporized material and may need to be cleaned to disassemble.

### SUMMARY

A mask assembly for a coating system according to one disclosed non-limiting embodiment of the present disclosure includes a second mask that mounts to the first mask and is retained thereto by a pin.

A further embodiment of the present disclosure includes, wherein the pin is a platter mount pin.

A further embodiment of any of the foregoing embodiments of the present disclosure includes, wherein the first mask includes a first pin aperture.

A further embodiment of any of the foregoing embodiments of the present disclosure includes, wherein the second mask includes a second pin aperture.

A further embodiment of any of the foregoing embodiments of the present disclosure includes, wherein the first mask includes a hook.

A further embodiment of any of the foregoing embodiments of the present disclosure includes, wherein the second mask includes a tab at least partially received in the hook.

A further embodiment of any of the foregoing embodiments of the present disclosure includes, wherein the first mask includes a hook and a first pin aperture.

A further embodiment of any of the foregoing embodiments of the present disclosure includes, wherein the second mask includes a tab and a second pin aperture.

A further embodiment of any of the foregoing embodiments of the present disclosure includes, wherein the first pin aperture is aligned with the second pin aperture when the second mask mounts to the first mask.

A further embodiment of any of the foregoing embodiments of the present disclosure includes, wherein the tab is at least partially received in the hook when the second mask mounts to the first mask.

A further embodiment of any of the foregoing embodiments of the present disclosure includes, wherein said first mask includes a hook and a first pin aperture, said hook extends from a first end of said first mask and said pin aperture in a second end of said first mask, said first end opposite said second end.

A further embodiment of any of the foregoing embodiments of the present disclosure includes, wherein said second mask includes a tab and a second pin aperture, said tab extends from a first end of said second mask and said second pin aperture in a second end of said second mask, said first end opposite said second end.

A further embodiment of any of the foregoing embodiments of the present disclosure includes, wherein said first mask includes a first interface and a first pin aperture, said first interface extends from a first end of said first mask, said pin aperture in a second end of said first mask, said first end opposite said second end.

A further embodiment of any of the foregoing embodiments of the present disclosure includes, wherein said second mask includes a second interface engageable with said first interface and a second pin aperture alignable with said first pin aperture.

A method of masking a component for a cathodic arc vapor deposition system according to another disclosed non-limiting embodiment of the present disclosure includes a retaining a first mask to a second mask with a platter mount pin.

A further embodiment of any of the foregoing embodiments of the present disclosure includes locating a rotor blade within the first mask and the second mask.

A further embodiment of any of the foregoing embodiments of the present disclosure includes locating the platter mount pin within a platter of the cathodic arc vapor deposition system.

A further embodiment of any of the foregoing embodiments of the present disclosure includes assembling a tab in the second mask into a hook of the first mask.

A further embodiment of any of the foregoing embodiments of the present disclosure includes aligning a first pin aperture of the first mask with a second pin aperture of the second mask.

The foregoing features and elements may be combined in various combinations without exclusivity, unless expressly indicated otherwise. These features and elements as well as the operation thereof will become more apparent in light of the following description and the accompanying drawings. It should be understood, however, the following description and drawings are intended to be exemplary in nature and non-limiting.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 is a schematic view of a cathodic arc vapor deposition system;

FIG. 2 is an exploded view of a mask assembly;

FIG. 3 is an assembled view of the mask assembly; and

FIG. 4 is a perspective view of two mask assemblies and a platter mount pin of a cathodic arc vapor deposition system platter.

### DETAILED DESCRIPTION

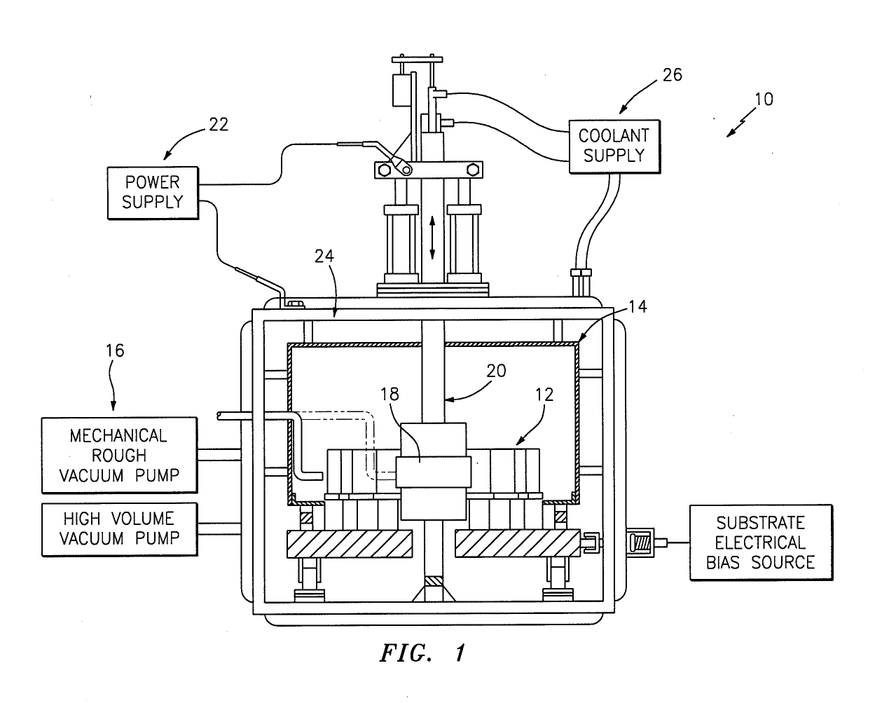

FIG. 1 schematically illustrates a coating system 10 such as cathodic arc vapor deposition system for cathodic arc vapor deposition onto a workpiece platter 12. The system 10 generally includes a vessel 14, a vacuum system 16 to maintain a vacuum in the vessel 14, a cathode 18, a contactor 20, a power supply 22 to sustain an arc of electrical energy between the cathode 18 and an anode 24, and a magnetic director 32 to steer the arc around the cathode 18. A water-cooler supply subsystem 26 maintains the system 10 within acceptable temperatures by cycling coolant through the vessel 14 and the contactor 20.

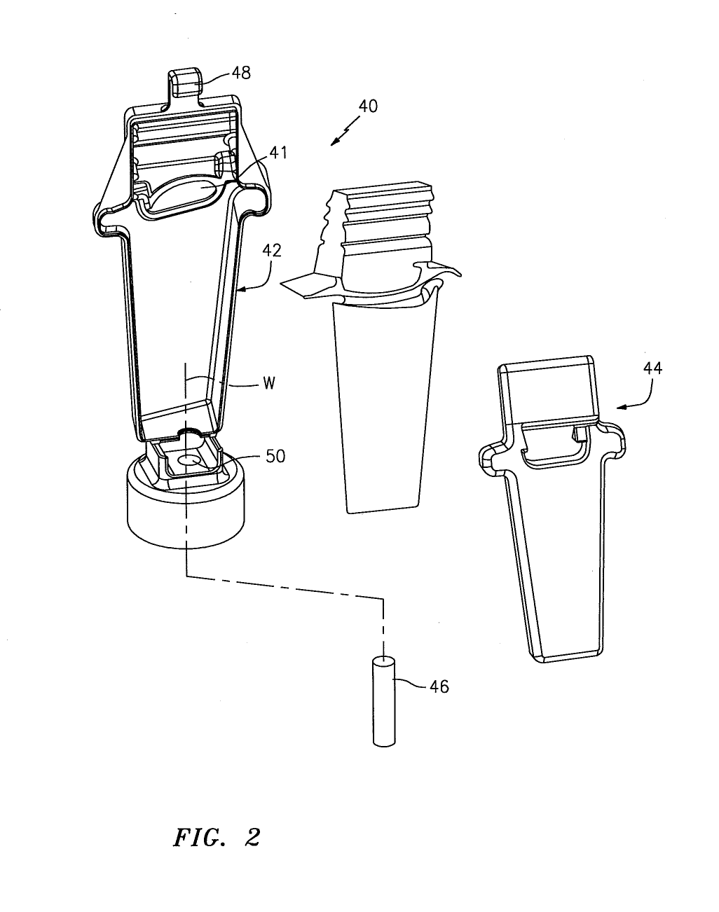

With reference to FIG. 2, the workpiece, such as a turbine blade 100 may be located within a mask assembly 40 to mask selected portions of the turbine blade 100 which are not to be coated. The turbine blade 100 generally includes an airfoil 102, a platform 104 and a root 106. It should be understood that various aerospace components such as vanes and static structures that require a section of the component to be masked will also benefit herefrom.

The mask assembly 40 include a window 41 to admit vaporized material from the cathodic arc vapor deposition system 10 to be, for example, deposited on the undersurface of the platform 104 as this area may be subjected to corrosive, oxidative gases. It should be appreciated that other areas and other components will also benefit herefrom.

The mask assembly 40 includes a first mask 42 and a second mask 44 that fit together and are retained by a platter mount pin 46 along axis W. The first mask 42 generally includes a first interface 48 such as a hook and a first platter mount pin aperture 50 on an opposite the first interface 48. The second mask 44 generally includes a second interface 52 such as a tab and a second platter mount pin aperture 52. It should be appreciated that various interfaces may be provides such as a hinge, flexible member or other arrangement may be provided.

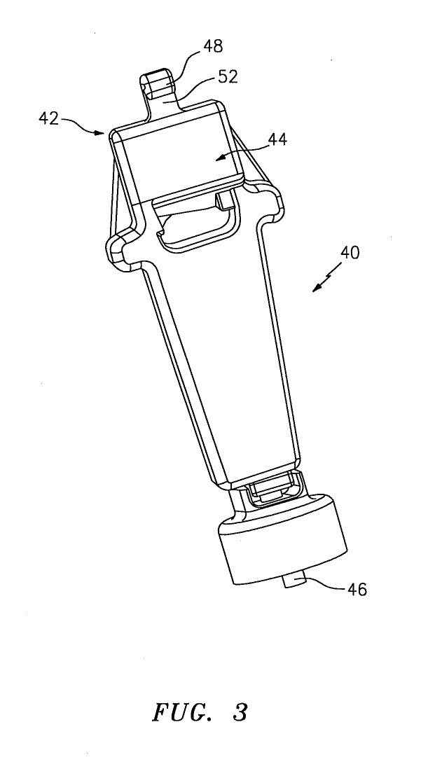

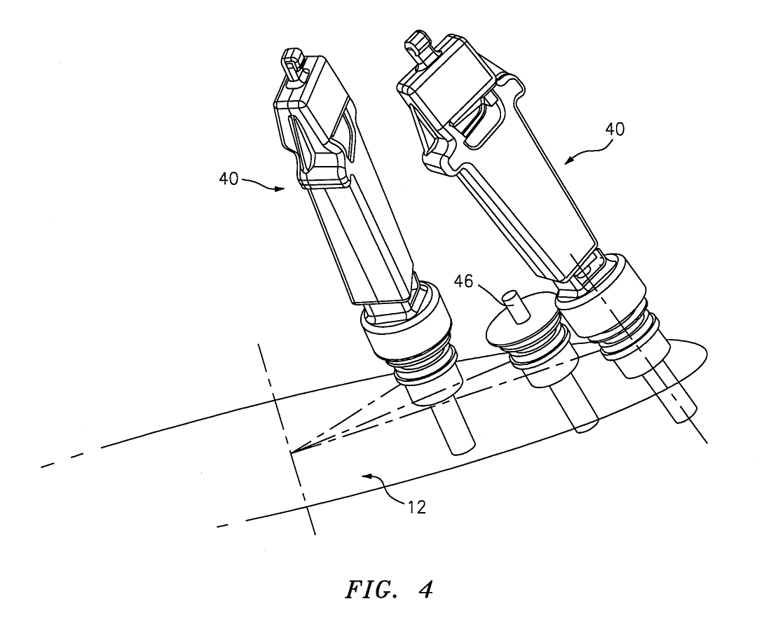

In operation, after the turbine blade 100 is located in the first mask 42, the second interface 52 is engaged with the first interface 48 and the first platter mount pin aperture 50 is aligned with the second platter mount pin aperture 52 (FIG. 3). The mask assembly 40 is then located onto the platter mount pin 46 of the platter 12 (illustrated schematically; FIG. 4) to retain and support the mask assembly 40 in an assembled condition. Assembly is thereby facilitated. Disassembly is also facilitated as the mask assembly 40 need only be removed from the platter mount pin 46. No mechanical threaded fasteners are required. This reduces the time to assemble, disassemble and clean the mask, reduces ergonomic issues, and improves cycle time to load the patter within the cathodic arc vapor deposition system 10.

It should be understood that like reference numerals identify corresponding or similar elements throughout the several drawings. It should also be understood that although a particular component arrangement is disclosed in the illustrated embodiment, other arrangements will benefit herefrom.

Although the different non-limiting embodiments have specific illustrated components, the embodiments of this invention are not limited to those particular combinations. It is possible to use some of the components or features from any of the non-limiting embodiments in combination with features or components from any of the other non-limiting embodiments.

Although particular step sequences are shown, described, and claimed, it should be understood that steps may be performed in any order, separated or combined unless otherwise indicated and will still benefit from the present disclosure.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be understood that within the scope of the appended claims, the disclosure may be practiced other than as specifically described. For that reason the appended claims should be studied to determine true scope and content.

What is claimed is:

1. A mask assembly for a coating system comprising:
a first mask; and
a second mask that mounts to said first mask and is retained thereto by a pin.

2. The mask assembly as recited in claim 1, wherein said pin is a platter mount pin.

3. The mask assembly as recited in claim 1, wherein said first mask includes a first pin aperture.

4. The mask assembly as recited in claim 3, wherein said second mask includes a second pin aperture.

5. The mask assembly as recited in claim 1, wherein said first mask includes a hook.

6. The mask assembly as recited in claim 5, wherein said second mask includes a tab at least partially received in said hook.

7. The mask assembly as recited in claim 1, wherein said first mask includes a hook and a first pin aperture.

8. The mask assembly as recited in claim 7, wherein said second mask includes a tab and a second pin aperture.

9. The mask assembly as recited in claim 8, wherein said first pin aperture is aligned with said second pin aperture when said second mask mounts to said first mask.

10. The mask assembly as recited in claim 9, wherein said tab is at least partially received in said hook when said second mask mounts to said first mask.

11. The mask assembly as recited in claim 1, wherein said first mask includes a hook and a first pin aperture, said hook extends from a first end of said first mask and said pin aperture in a second end of said first mask, said first end opposite said second end.

12. The mask assembly as recited in claim 11, wherein said second mask includes a tab and a second pin aperture, said tab extends from a first end of said second mask and said second pin aperture in a second end of said second mask, said first end opposite said second end.

13. The mask assembly as recited in claim 1, wherein said first mask includes a first interface and a first pin aperture, said first interface extends from a first end of said first mask, said pin aperture in a second end of said first mask, said first end opposite said second end.

14. The mask assembly as recited in claim 13, wherein said second mask includes a second interface engageable with said first interface and a second pin aperture alignable with said first pin aperture.

15. A method of masking a component for a cathodic arc vapor deposition system comprising:
retaining a first mask to a second mask with a platter mount pin.

16. The method as recited in claim 15, further comprising:
locating a rotor blade within the first mask and the second mask.

17. The method as recited in claim 15, further comprising:
locating the platter mount pin within a platter of the cathodic arc vapor deposition system.

18. The method as recited in claim 15, further comprising:
assembling a tab in the second mask into a hook of the first mask.

19. The method as recited in claim 18, further comprising:
aligning a first pin aperture of the first mask with a second pin aperture of the second mask.
